(19) United States
(12) Patent Application Publication
(10) Pub. No.: US 2004/0108521 A1
(43) Pub. Date: Jun. 10, 2004

(54) Temperature adaptive refresh clock generator for refresh operation

(76) Inventors: Jung-Don Lim, Seoul (KR); Mi-Kyeong Yun, Seongnam-si (KR)

Correspondence Address: SHERIDAN ROSS PC, 1560 BROADWAY, SUITE 1200, DENVER, CO, 80202

(21) Appl. No.: 10/726,320

(22) Filed: Dec. 1, 2003

(30) Foreign Application Priority Data
Dec. 4, 2002 (KR) 2002-76716

(51) Int. Cl. H01L 31/0328

(52) U.S. Cl. 257/200

(57) ABSTRACT

A clock generator generating a refresh clock signal used in a refresh execution of a semiconductor includes a first MOS transistor diode-connected for outputting a first bias voltage, a source of the first MOS transistor being connected to a supply voltage; a second MOS transistor diode-connected for outputting a second bias voltage, a source of the second MOS transistor being connected to ground voltage; a bias current control means having a predetermined number of serial-connected diodes for serving as a resistance in inverse proportion to a temperature, wherein the bias current control means is coupled between the first MOS transistor and the second MOS transistor to control the first and second bias voltages by using the resistance; and a refresh clock generator generating the refresh clock signal having the frequency which is controlled or adjusted based on the first and second bias voltages.

### FIELD OF THE INVENTION

The present invention relates to semiconductor memory devices, and more particularly, to a refresh clock generator for controlling refresh operation adaptive to a temperature variation.

### DESCRIPTION OF RELATED ART

In general, semiconductor memory device can be classified by Random Access memory (hereinafter, referred as RAM) and Read Only memory (hereinafter, referred as ROM). The RAM is volatile, but the ROM is nonvolatile. Namely, the ROM can keep stored data even though power supply is removed, but the RAM cannot keep stored data if the power supply is removed.

The RAM can be further classified by Dynamic Random Access memory DRAM (hereinafter, referred as DRAM) and Static Random Access memory SRAM (hereinafter, referred as SRAM). The SRAM has at least one cell block including a plurality of memory cells. Each memory cell includes four transistors that constitute a latch for storing data. In contrast, the memory cell of the DRAM has one transistor and one capacitor for storing data. According to the capacitor's characteristic, a charge of stored data in the capacitor is reduced in proportion with data storing time. So, the DRAM needs a periodic refresh operation that constantly refreshes the memory cells in order to maintain data stored therein.

In addition, the DRAM receives a column address and a row address for selecting the memory cell. The row address is converted to a signal for selecting one of word lines included in the cell block and the column address is converted to a signal for selecting one of bit lines included in the cell block.

In the DRAM, one cycle of the refresh operation includes following steps: selecting the word line in the cell block; amplifying charge of stored data in the capacitors in response to the word line; and restoring the amplified data in the capacitors. Of course, the word lines are sequentially selected at every cycle of the refresh operation. Throughout the refresh operation, each stored data is restored in each memory cell without any charge loss.

In the refresh operation, the DRAM needs a refresh clock for selecting a different word line at every cycle. A refresh clock generator for the refresh operation is used in generating the refresh clock and the refresh operation is performed on the basis of the refresh clock.

FIG. 1 is a block diagram of a conventional refresh circuit.

As shown, the refresh circuit for refresh operation includes a refresh clock generating unit 10 and a refresh operation unit 30. The refresh clock generating unit 10 is used to generate a refresh clock signal and includes a bias voltage generator 11 and a clock generator 12. The bias voltage generator 11 generates first and second bias voltages Vp and Vn which are coupled to the clock generator 12. The bias voltages Vp and Vn are used in determining a frequency of the refresh clock signal outputted from the clock generator 12. The clock generator 12 generates the refresh clock signal frequency-controlled by using the first and second bias voltages Vp and Vn, and the refresh clock signal is then supplied to the refresh operation unit 30. The refresh operation unit 30 receives the refresh clock signal and executes the refresh operation based thereon.

FIG. 2 is a schematic circuit diagram of the bias voltage generator 11 and the clock generator 12 included in the refresh clock generation unit shown in FIG. 1.

The bias voltage generator 11 includes a PMOS transistor MP1, a resistor R, and a NMOS transistor MN1. The drain of the PMOS transistor MP1 is connected to a supply voltage source VDD. The gate of the PMOS transistor MP1 is connected to it's source to generate the first bias voltage Vp. The resistor R is connected between the source of the PMOS transistor MP1 and the drain of the NMOS transistor MN1. The source of the NMOS transistor MN1 is connected to a ground voltage source VSS. The gate of the NMOS transistor MN1 is connected to it's drain to output the second bias voltage Vn.

The clock generator 12 includes several serial-connected delay controllable inverters IN_1, IN_2, . . . , and IN_{—}n. Like a ring oscillator, output of the last delay controllable inverter IN_{—}n is coupled back to input of the first delay controllable inverter IN_1 and also coupled, as a refresh clock, to the refresh operation unit shown in FIG. 1.

First delay controllable inverter IN_1 has PMOS transistors MP22 and MP23 and NMOS transistors MN22 and MN23. The PMOS transistor MP23 and the NMOS transistor NM23 are operated as an inverter. The PMOS transistor MP22 and the NMOS transistor MN22 serve as a delay switch of the inverter IN_1. The first and second bias voltages Vp and Vn are inputted at gates of them and a control delay value of the inverter IN_1 is respectively controlled or adjusted depend on the first and the second bias voltage Vp and Vn.

In the clock generator 12, each delay controllable inverter receives output of the proceeding delay controllable inverter and provides an inversed output signal as an output signal to be coupled to the next delay controllable inverter. The last delay controllable inverter IN_{—}n outputs the refresh clock signal to the first delay controllable inverter IN_1 and the refresh operation block 30.

FIG. 3 describes a graph showing a relationship of a reference current Iref1 and a temperature in the bias voltage generator 11 shown in FIG. 2. FIG. 4 shows a graph showing a characteristic of the refresh frequency versus a temperature in the clock generator 12 described in FIG. 2.

Hereinafter, referring to the accompanying drawings from FIGS. 1 to 4, the conventional refresh clock generating unit will be described in detail.

First of all, if the supply voltage source VDD and the ground voltage source VSS are provided to the refresh circuit, the PMOS transistor MP1 and the NMOS transistor MN1 of the bias voltage generator 11 are turned on. As a result, a predetermined reference current Iref1 is flowed from the supply voltage source VDD to the ground voltage source VSS through resistor R. If the reference current Iref1 flows through the resistor R, each gate of the PMOS transistor MP1 and the NOMS transistor MN1 is supplied with each bias voltage Vp/Vn which is coupled to the clock generator 12.

Subsequently, the several delay controllable inverters IN_1, IN_2, . . . , and IN_n of the clock generator 20 are enabled by the first and second predetermined bias voltages Vp and Vn used in determining delay value of each delay controllable inverter. The clock generator 20 generates the refresh clock signal which is provided to the refresh operation unit 30. The operation of the clock generator 20 is similar to that of a well known ring oscillator, and therefore, for the sake of convenience, no further explanation thereon will be described.

On the other hand, if a temperature of the bias voltage generator 10 is increased, a resistance of the resistor R is increased so that the voltage drop across the resistor R is increased. Thus, the first bias voltage Vp is increased and the second bias voltage Vn is decreased.

If the first bias voltage Vp is increased, amount of charges through channel of PMOS transistors MP22, MP24, and MP26 in each delay controllable inverter is decreased. In addition, amount of charges through channel of NMOS transistors MN22, MN24, and MN26 in each delay controllable inverter is decreased if the second bias voltage Vn is decreased. As a result, each delay controllable inverter has a longer delay value so that the frequency of the refresh clock signal becomes lower.

As described above, the voltage levels of the first and second bias voltages Vp and Vn are used in determining a frequency of the refresh clock. As a result, the frequency of the refresh clock is varied in inverse proportion to the temperature, as shown in FIG. 4.

However, it is desired that the period of the refresh operation should be decreased in proportion to the temperature because stored charge leakage of the capacitor in the DRAM is increased in proportion to the temperature. If the temperature is high, stored data in DRAM would loss quickly because of increasing charge leakage. If the temperature is low, stored data would be maintained for relatively long time because charge leakage is slowly occurred. Namely, the desired refresh period should be decreased in proportion to a temperature.

However, if a conventional DRAM uses the refresh clock outputted from the refresh clock generating unit shown in FIGS. 1 and 2 according to the prior art, there is often occurred critical problem that charge leakage is largely increased in a high temperature because of the longer refresh frequency and power consumption is dramatically increased in a low temperature due to unnecessary refresh operation.

### SUMMARY OF THE INVENTION

It is, therefore, an object of the present invention to provide a clock generator for DRAM refresh operation which outputs a refresh clock that can optimally control a refresh period by temperature variation.

In accordance with an aspect of the present invention, there is provided a clock generator generating a refresh clock signal used in a refresh execution of a semiconductor including a first MOS transistor diode-connected for outputting a first bias voltage, a source of the first MOS transistor being connected to a supply voltage; a second MOS transistor diode-connected for outputting a second bias voltage, a source of the second MOS transistor being connected to ground voltage; a bias current control means having a predetermined number of serial-connected diodes for serving as a resistance in inverse proportion to a temperature, wherein the bias current control means is coupled between the first MOS transistor and the second MOS transistor to control the first and second bias voltages by using the resistance; and a refresh clock generator generating the refresh clock signal having the frequency which is controlled or adjusted based on the first and second bias voltages.

### BRIEF DESCRIPTION OF THE DRAWINGS

The above and other objects and features of the present invention will become apparent from the following description of preferred embodiments taken in conjunction with the accompanying drawings, in which:

FIG. 1 is a block diagram of a conventional refresh circuit;

FIG. 2 is a schematic circuit diagram of the bias voltage generator and the clock generator included in the refresh clock generating unit shown in FIG. 1;

FIG. 3 describes a graph showing a relationship of a reference current and a temperature in the bias voltage generator shown in FIG. 2;

FIG. 4 shows a graph showing a characteristic of the refresh frequency versus a temperature in the clock generator described in FIG. 2;

FIG. 5 is a schematic circuit diagram of a refresh clock generating unit in accordance with a preferred embodiment of the present invention;

FIGS. 6A and 6B are circuit diagrams of MOS transistors operated as the diode in a bias current control logic shown in FIG. 5;

FIG. 7 is a graph showing an operation theory of a refresh clock generating unit in accordance with the present invention;

FIG. 8 describes a graph showing a relationship of the reference current and the temperature in a bias voltage generator shown in FIG. 5; and

FIG. 9 shows a graph showing the characteristic of a refresh frequency versus temperature of a clock generator described in FIG. 5.

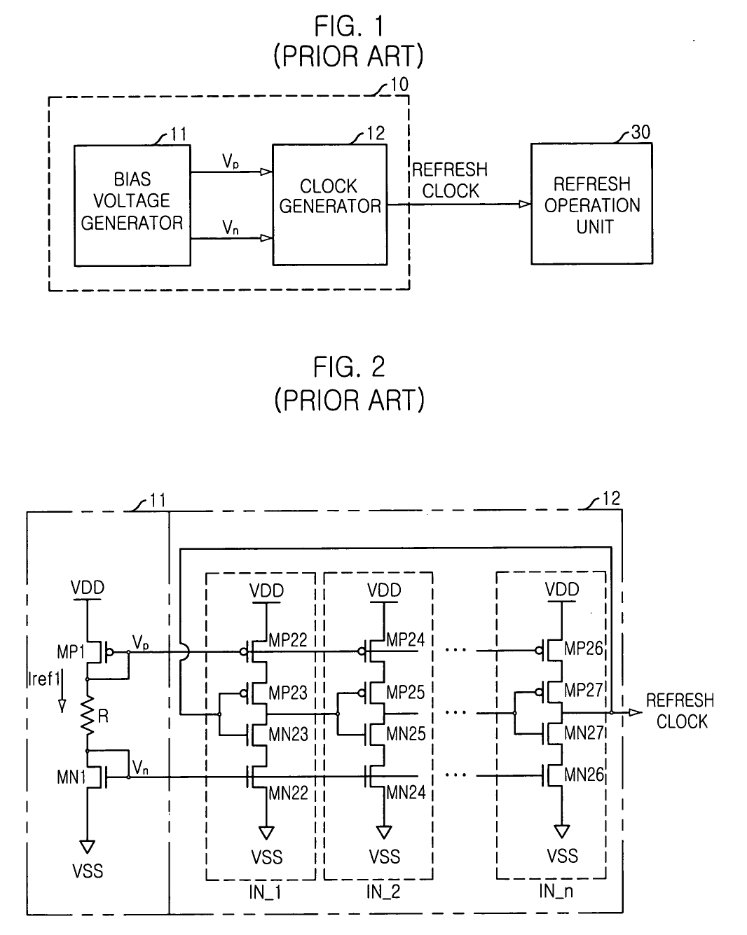

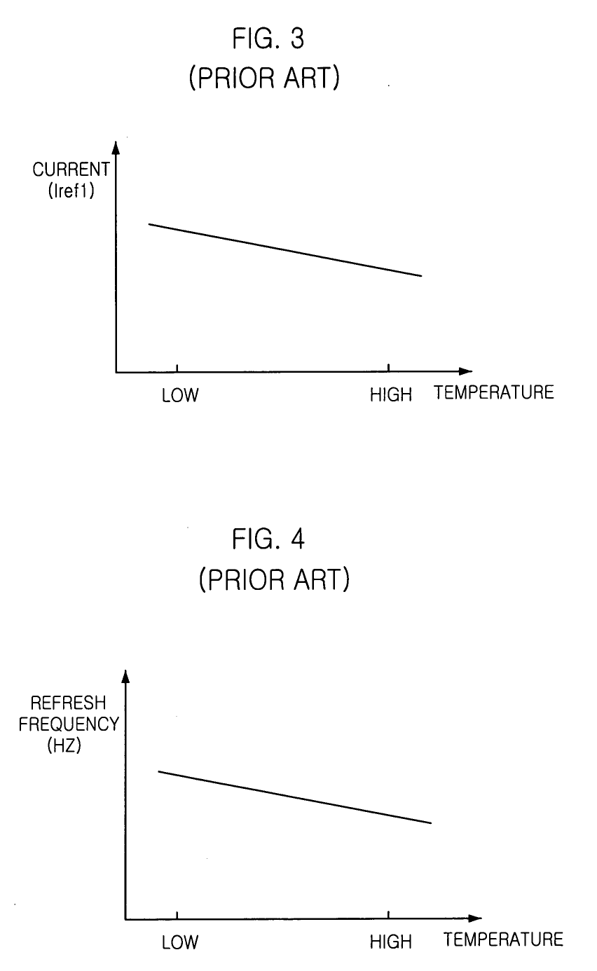

### DETAILED DESCRIPTION OF THE INVENTION

Hereinafter, a refresh clock generator according to the present invention will be described in detail referring to the accompanying drawings.

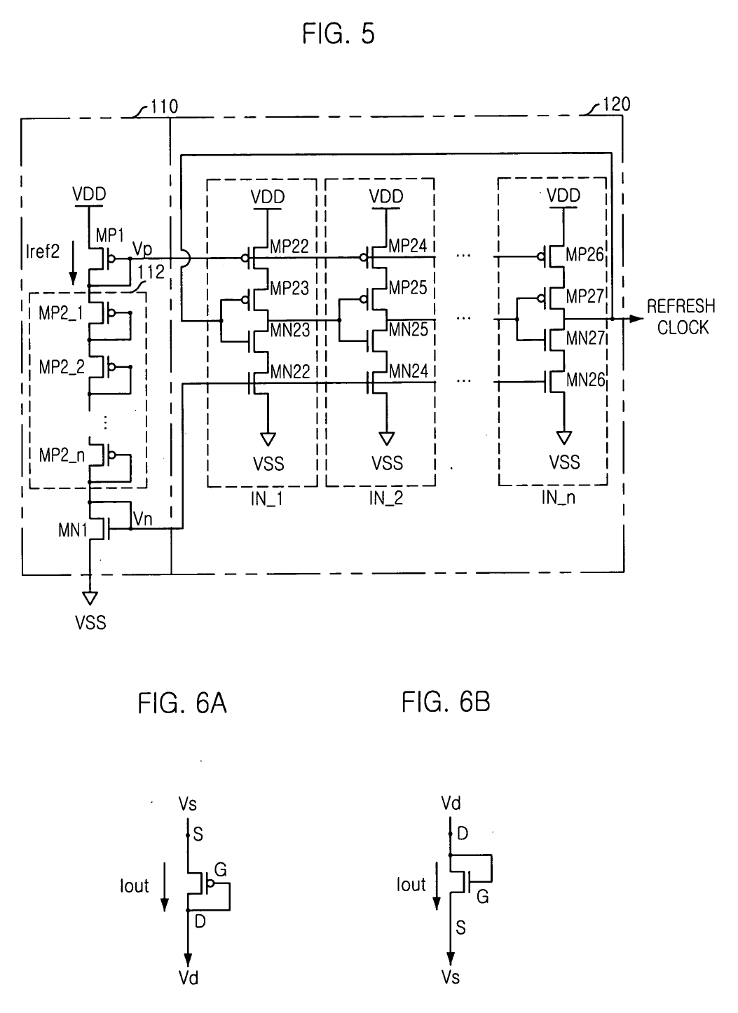

FIG. 5 is a schematic circuit diagram of a refresh clock generating unit in accordance with a preferred embodiment of the present invention.

As shown, the refresh clock generating unit in accordance with the present invention includes a bias voltage generator 110 for outputting first and second bias voltages Vp and Vn and a clock generator 120 for outputting a refresh clock signal. The bias voltages Vp and Vn are used in determining a frequency of the refresh clock signal outputted from the clock generator 120.

The bias voltage generator 110 includes a PMOS transistor MP1, a NMOS transistor MN1, and a bias current control logic 112. The gate of the PMOS transistor MP1 is connected to it's drain to output the first bias voltage Vp. In the NMOS transistor MN1, the gate is connected to drain to output the second bias voltage Vn. The bias current control logic 112 between the PMOS and NMOS transistors MP1 and MN1 has several serial-connected MOS transistors MP2_1, MP2_2, . . . , and MP2_n. Each MOS transistor MP2_1, MP2_2, . . . , MP2_n is operated as a diode and as a resistor. There should be at least more a number of the diode than value which divides a supply voltage VDD into a threshold voltage Vth of the diode. For example, if VDD=2.5V and Vth=0.7, there are at least four diodes.

The clock generator 120 includes several serial-connected delay controllable inverters IN_1, IN_2, . . . , and IN_n. Like a ring oscillator, output of the last delay controllable inverter IN_n is coupled to input of the first delay controllable inverter IN_1. The structure and operation of the clock generator 120 is similar to those of the clock generator 12 shown in FIG. 2 and, therefore, for the sake of convenience, no further explanation about those will be described.

FIGS. 6A and B are exemplary circuit diagrams of MOS transistors operated as the diode in the bias current control logic 112 shown in FIG. 5.

Referring to FIG. 6A, the gate G is connected to the drain D so that the PMOS transistor is operated as the diode. In contrast, referring to FIG. 6B, the gate G is connected to the drain D so that the NMOS transistor is operated as the diode. Herein, a current Iout flowed through the MOS transistor is determined by a voltage gap Vds between the drain and the source of the MOS transistor.

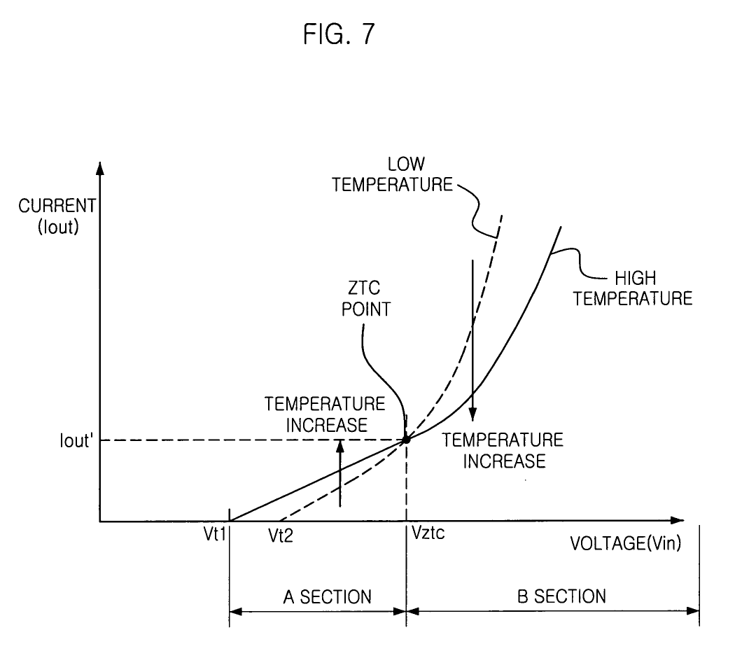

FIG. 7 is a graph showing an operation charateristic of the refresh clock generating unit in accordance with the present invention. Hereinafter, referring to FIGS. 5 to 7, the refresh clock generating unit in accordance with the present embodiment is described in detail.

In the bias current control logic 112, if the MOS transistors are diode-connected, the current Iout flowed through the diode-connected MOS transistors can be described by using following Eq. 1. In the following explanation, there is described a characteristic of the diode-connected transistor without distinction between the PMOS transistor and the NMOS transistor because the characteristic of the diode formed by the PMOS transistor is similar to that formed by the NMOS transistor.

Iout=½μ(T)×Cox×W/L[V_{DS}−|Vth(T)|]² (Eq.1)

In Eq. 1, Vth is a threshold voltage of MOS transistor; Vth(T) is derived by following Eq. 2; μ is a carrier mobility of MOS transistor. Herein, the carrier is either an electron if the transistor is a NMOS transistor or a hole if the transistor is a PMOS transistor. μ(T) is derived by following Eq. 3. Cox is a capacitance by a gate oxide of MOS transistor; W/L is a width/length of channel; and VDS is a voltage gap between drain and source.

Vth(T)≈Vth₀−a(T−T₀) (Eq. 2)

[a=0.5˜5 mV/° K, Vth₀=Vth at normal temperature (T=298° K)]

μ(T)≈μ₀×T^{-3/2} (Eq. 3)

[μ₀=μ at normal temperature (T=298° K)]

Above Eq. 2 and Eq. 3 are applied to Eq. 1, then following equation is derived.

Iout=½×μ₀×T^{-3/2}×Cox×W/L[V_{DS}−|Vth₀−a(T−T₀)|]² (Eq. 4)

Referring to Eq. 4, the current Iout flowed through the diode-connected MOS transistor is in inverse proportion to the temperature because of the character of mobility μ and the character of threshold voltage Vth.

As shown in FIG. 7, because of a characteristic of the current Iout flowed through the diode-connected MOS transistor, there are two curves about relationship of the current Iout and the voltage gap Vin between the drain and the source of the diode-connected MOS transistor at the high and low temperature. In addition, there is a cross point of two curves. The cross point is called a zero temperature coefficient point (hereinafter, referred as ZTC point) and marked as ‘Vztc’ in the FIG. 7. Namely, if the voltage gap Vin is ‘Vztc’, the current Iout is predetermined unrelated to a temperature variation. Herein, the threshold voltages in response to the temperature are marked as Vt1 and Vt2 in the FIG. 7. The Vt1 is a threshold voltage at high temperature and the Vt2 is the threshold voltage at low temperature.

If the voltage gap between sides of the diode-connected MOS transistor is below ‘Vztc’ denoted as A SECTION, the function of threshold voltage {Vth₀−a(T−T₀)} is more dominant than function of mobility (μ₀×T^{-3/2}). So, the more temperature is high, the more amount of the current Iout is flowed through the diode-connected MOS transistor. In contrast, if the voltage gap between sides of the diode-connected MOS transistor is above ‘Vztc’ designated as B SECTION, the function of mobility (μ₀×T^{-3/2}) is more dominant than the function of threshold voltage {Vth₀−a(T−T₀)}. So, the more temperature is low, the more amount of the current Iout is flowed through the diode-connected MOS transistor.

Thus, the current is increased in proportion to the temperature if the voltage gap between sides of the diode-connected MOS transistor is between the threshold voltages Vt1 and Vt2 and Vztc point. As a result, the first bias voltage Vp is increased in proportion to the temperature and the second bias voltage Vn is decreased in proportion to the temperature; however, because the threshold voltage Vt is dramatically decreased, the current can increased.

In the bias current control logic 112, for the sake of being the voltage gap between drain and source of the diode-connected MOS transistor in the range between the threshold voltage Vth and Vztc point, the number of the diode-connected MOS transistors that constitute the bias current control device 112 are determined by the supply voltage VDD and the threshold voltage Vth of the diode-connected MOS transistor.

For instance, there is assumed that the supply voltage is 2.5V, the threshold voltage is 0.7V, and about four to six of the diode-connected MOS transistors are serially connected. If the number of the diode-connected MOS transistors are larger than the value which divides the supply voltage 2.5V by the threshold voltage 0.7V, the first and second bias voltages Vp and Vn are determined between the threshold voltage Vth and Vztc point. At here, four to six can be a proper number of diodes. As a result, the first and second bias voltages Vp and Vn outputted from the gate of the first and second MOS transistors MP1 and MN1 are determined between the threshold voltage Vth and Vztc point.

Of course, in above case, it is possible that three to four of the diode-connected MOS transistors are serially connected so that the first and second bias voltages Vp and Vn are determined between the threshold voltage Vth and Vztc point.

Thus, if a number of the diode-connected MOS transistors that constitute the bias current control device 112 are controlled, the current Iref2 flowed through the bias voltage generator 100 is increased in proportion to the temperature. As a result, the first bias voltage Vp is decreased and the second bias voltage Vn is increased in proportion to the temperature.

The clock generator 200 that is similar to structure of a ring oscillator outputs the refresh clock of which frequency is increased or decreased in response to the bias voltages after receiving the first and second bias voltages Vp and Vn. If the refresh operation is occurred in response to the refresh clock, the period of the refresh operation is short at high temperature and the period of the refresh operation is long at a low temperature.

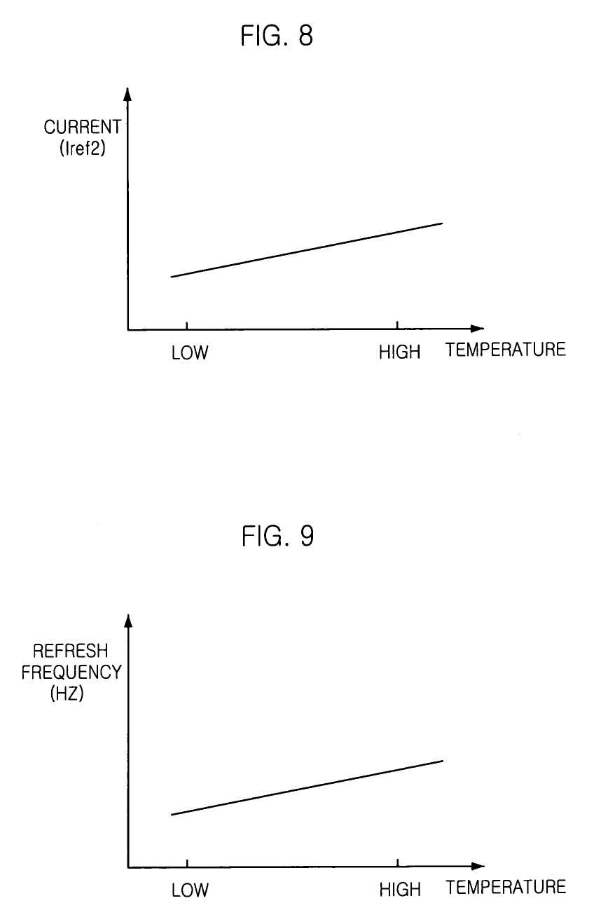

FIG. 8 describes a graph showing a relationship of the reference current Iref2 and the temperature in bias voltage generator 110 shown in FIG. 5.

As shown, if the temperature is increased, the current Iref2 flowed through the bias voltage generator 110 is increased. So, the first bias voltages Vp is decreased and the second bias voltage Vn is increased. In contrast, if the temperature is decreased, the current Iref2 is decreased. So, the first bias voltage Vp is increased and the second bias voltages Vn is decreased.

FIG. 9 shows a graph showing the characteristic of the refresh frequency versus temperature of the clock generator 120 described in FIG. 5.

As shown, a frequency of the refresh clock signal outputted from the refresh clock generator 120 is in proportion to the temperature, since the first bias voltage Vp is decreased and the second bias voltages Vn is increased in proportion to the temperature increase. If it is high temperature, the DRAM needs more frequent refresh operation; otherwise, the refresh operation performed frequently in the DRAM not only is unnecessary, but also result in large current consumption. Thus, if the refresh operation is performed by the refresh clock outputted from the refresh clock generator in accordance with the present invention, the refresh operation has the preferred refresh period in response to temperature variation. In addition, the unnecessary refresh operation is not occurred at low temperature, so the current consumption can be decreased in an effective manner.

Referring back to FIG. 5, if the bias current control device 112 is supplied with supply voltage VDD, the threshold voltage Vth of each PMOS transistor MP2_1, MP2_2, . . . , and MP2_{—}n can be induced by the following Eq. 5.

Vth=Vth₀+a[(2|Φp|+|Vsb|)^{1/2}]−(2|Φp|^{1/2}) (Eq. 5)

wherein a: constant ratio; Vsb: voltage gap between a source and a substrate bulk; Φ p: the electric potential of the substrate bulk.

As shown, absolute value of threshold |Vth| of the PMOS transistor MP2_2 is substantially larger than that of the PMOS transistor MP2_1. As a result, the absolute value of the last. PMOS transistor MP2_{—}n is the largest value because the PMOS transistor MP2_{—}n has more absolute value of threshold |Vth| than the previous PMOS transistor MP2_{—}n−1. It means that the final PMOS transistor MP2_{—}n has the largest resistance if each diode-connected PMOS transistor is regarded as a resistor. Namely, the final PMOS transistor MP2_{—}n gives the most effect to the current Iref2 flowed through the bias voltage generator 100.

Therefore, the final MOS transistor MP2_{—}n is the most critical value so that the first and second bias voltages Vp and Vn stand between the threshold voltage Vth and Vztc point.

In additional manner, for controlling the resistance of the bias current control device 122, it is effective to adjust W/L ratio of the final MOS transistor MP2_{—}n without adding any new diode-connected MOS transistors because the resistance of the MOS transistor is varied in response to the Width/Length ratio.

If a refresh operation is occurred in response to the refresh clock signal outputted from the refresh clock generator in accordance with the present invention, the refresh operation has a preferred characteristic of the frequency versus temperature variation of the refresh clock generator.

Also, if the refresh period is controlled in response to the temperature variation, the unnecessary refresh operation is not performed. So, total current consumption in the refresh clock generator is surprisingly reduced.

While the present invention has been described with respect to the particular embodiments, it will be apparent to those skilled in the art that various changes and modifications may be made without departing from the spirit and scope of the invention as defined in the following claims.

What is claimed is:

1. A clock generator generating a refresh clock signal used in a refresh execution of a semiconductor, comprising:
a first MOS transistor diode-connected for outputting a first bias voltage, a source of the first MOS transistor being connected to a supply voltage;
a second MOS transistor diode-connected for outputting a second bias voltage, a source of the second MOS transistor being connected to ground voltage;
a bias current control means having a predetermined number of serial-connected diodes for serving as a resistance in inverse proportion to a temperature, wherein the bias current control means is coupled between the first MOS transistor and the second MOS transistor to control the first and second bias voltages by using the resistance; and
a refresh clock generator generating the refresh clock signal having the frequency which is controlled or adjusted based on the first and second bias voltages.

2. The clock generator of claim 1, wherein the predetermined number is greater than value which divides the supply voltage by a threshold voltage of the diode.

3. The clock generator of claim 2, wherein the predetermined number is at least four.

4. The clock generator of claim 2, wherein each serial-connected diode is a diode-connected PMOS transistor.

5. The clock generator of claim 2, wherein each serial-connected diode is a diode-connected NMOS transistor.

6. The clock generator of claim 2, wherein the refresh clock generator is configured by using a ring oscillator having a number of inverters.

7. The clock generator of claim 6, wherein the inverter includes:
a third MOS transistor for building a current mirror with the first MOS transistor, source of the third MOS transistor is connected to the supply voltage and gate of the third MOS transistor is connected to gate of the first MOS transistor; and
a forth MOS transistor for building a current mirror with said the second MOS transistor, source of the forth MOS transistor is connected to the ground voltage and gate of the forth MOS transistor is connected to gate of the second MOS transistor.

8. The clock generator of claim 1, wherein an operating voltage of the serial-connected diodes included in the bias current control means is varied between a threshold voltage and a ZTC point.

9. A semiconductor device having a refresh operation unit for performing a refresh operation in response to a refresh clock, comprising:
a first MOS transistor diode-connected for outputting a first bias voltage, a source of the first MOS transistor being connected to a supply voltage;
a second MOS transistor diode-connected for outputting a second bias voltage, a source of the second MOS transistor being connected to ground voltage;
a bias current control means having a predetermined number of serial-connected diodes for serving as a resistance in inverse proportion to a temperature, wherein the bias current control means is coupled between the first MOS transistor and the second MOS transistor to control the first and second bias voltages by using the resistance; and
a refresh clock generator generating the refresh clock signal having the frequency which is controlled or adjusted based on the first and second bias voltages.

10. The semiconductor device of claim 9, wherein the predetermined number is greater than value which divides the supply voltage by a threshold voltage of the diode.

11. The semiconductor device of claim 10, wherein the predetermined number is at least four.

12. The semiconductor device of claim 10, wherein each serial-connected diode is a diode-connected PMOS transistor.

13. The semiconductor device of claim 10, wherein each serial-connected diode is a diode-connected NMOS transistor.

14. The semiconductor device of claim 10, wherein the refresh clock generator is configured by using a ring oscillator having a number of inverters.

15. The semiconductor device of claim 14, wherein the inverter includes:
a third MOS transistor for building a current mirror with the first MOS transistor, source of the third MOS transistor is connected to the supply voltage and gate of the third MOS transistor is connected to gate of the first MOS transistor; and
a forth MOS transistor for building a current mirror with said the second MOS transistor, source of the forth MOS transistor is connected to the ground voltage and gate of the forth MOS transistor is connected to gate of the second MOS transistor.

16. The semiconductor device of claim 9, wherein an operating voltage of the serial-connected diodes included in the bias current control means is varied between a threshold voltage and a ZTC point.
